(19) United States
(12) Patent Application Publication
(10) Pub. No.: US 2008/0055200 A1
(43) Pub. Date: Mar. 6, 2008

(54) HIGH VOLTAGE GATE DRIVER IC WITH MULTI-FUNCTION GATING

(76) Inventors: Dong Young Lee, Torrance, CA (US); Min Fang, Redondo Beach, CA (US)

Correspondence Address: OSTROLENK FABER GERB & SOFFEN, 1180 AVENUE OF THE AMERICAS, NEW YORK, NY, 100368403, US

(21) Appl. No.: 11/848,501

(22) Filed: Aug. 31, 2007

Related U.S. Application Data
(60) Provisional application No. 60/824,335, filed on Sep. 1, 2006.

(51) Int. Cl. G09G 3/28; H03K 17/00

(52) U.S. Cl. 345/60

(57) ABSTRACT

A high voltage gate driver circuit in accordance with an embodiment of the present application includes a first driver operable to provide a first output voltage signal, a second driver operable to provide a second output voltage signal, internal circuitry operable to process the second output voltage signal to provide a processed output voltage signal having different characteristics than the first output voltage signal and a selection circuit operable to select one of the first output voltage signal and the processed output voltage signal as a gate drive signal. The high voltage gate driver may also include a single external power switch connected to the selection circuit such that the gate drive signal is provided to the gate of the external power switch to turn the external power switch on and off as desired.

### CROSS-REFERENCE TO RELATED APPLICATION

The present application claims the benefit of and priority to U.S. Provisional Patent Application Ser. No. 60/824,335, filed on Sep. 1, 2006 and entitled HIGH VOLTAGE GATE DRIVER IC (HVIC) WITH MULTIPLE GATING FUNCTIONS, the entire contents of which are hereby incorporated by reference herein.

### BACKGROUND OF THE INVENTION

The present invention relates to an improved high voltage gate driver circuit, and more particularly to a driver circuit for use with a Plasma Display Panel (PDP) that provides multiple gating functions while reducing the number of external power switches and other external components.

FIG. 1 is an illustration of a conventional high voltage gate driver integrated circuit 10 for use with a PDP. Plasma display panels typically include a matrix of cells, each of which including a gas that is converted into plasma by application of a voltage across the cell. In monochrome display panels, the ionized gas itself emits photons as the charged particles flow toward one of the electrodes used apply the ionizing voltage. In color plasma display panels, a phosphor coating is preferably applied to one of the surfaces of the cell which emits color light when stimulated by photons emitted by the ionized gas. In the circuit of FIG. 1, the external power switches 14a, 14b are used to control the voltage provided to the PDP.

Specifically, the circuit 10 includes two separate drivers 12a, 12b, which are used to control the switches Q1a, Q2a and Q1b, Q2b, respectively, to provide the output voltages Vouta, Voutb that are used to control the gates of the power switches 14a, 14b, respectively. The power switches 14a, 14b, respectively, are used to provide the ionizing voltage, or scanning voltage, designated Vscan in FIG. 1. External circuitry 16 may also be provided to provide additional functionality. For example, the circuitry 16 may be used to control dv/dt of the voltage provided by the circuit 10 to the PDP, if desired. Thus, the HVIC of FIG. 1 requires multi-channel drivers 12a, 12b, the external auxiliary circuitry 16 and two external power switches 14a, 14b in order to provide multi-function gating. As a result, such conventional gate driver circuits require substantial space and have a relatively high cost.

Accordingly, it would be beneficial to provide a high voltage gate driver integrated circuit that avoids these problems.

### SUMMARY OF THE INVENTION

It is an object of the present invention to provide a high voltage gate driver circuit with multi-function gating that reduces the number of external components necessary.

A high voltage gate driver circuit in accordance with an embodiment of the present application includes a first driver operable to provide a first output voltage signal, a second driver operable to provide a second output voltage signal, internal circuitry operable to process the second output voltage signal to provide a processed output voltage signal having different characteristics than the first output voltage signal and a selection circuit operable to select one of the first output voltage signal and the processed output voltage signal as a gate drive signal. The high voltage gate driver may also include a single external power switch connected to the selection circuit such that the gate drive signal is provided to the gate of the external power switch to turn the external power switch on and off as desired.

Other features and advantages of the present invention will become apparent from the following description of the invention that refers to the accompanying drawings.

### BRIEF DESCRIPTION OF THE DRAWINGS

FIG. 1 is a schematic of a conventional high voltage gate driver integrated circuit that provides multi-function gating.

FIG. 2 is a schematic diagram of a high voltage gate driver circuit in accordance with an embodiment of the present application.

### DETAILED DESCRIPTION OF EMBODIMENTS OF THE INVENTION

The present invention relates to a high voltage gate driver circuit that provides multi-function gating with a reduced number of external components. As a result, both complexity and the space required by the circuit are reduced while maintaining high functionality.

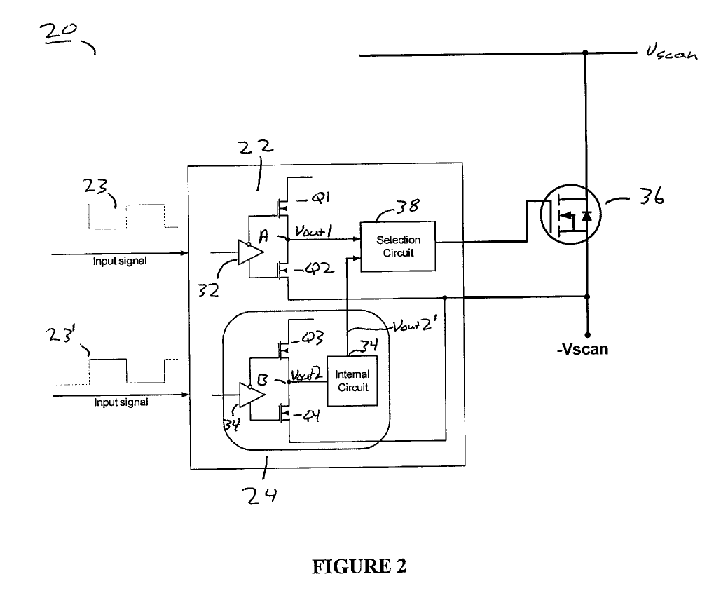

A high voltage gate driver circuit 20 in accordance with an embodiment of the present invention is described in further detail with reference to FIG. 2. The driver circuit 20 preferably includes a first driver 22 and a second driver 24 operable to provide output signals Vout1 and Vout2, respectively. The first and second drivers 22, 24 preferably provide different gating characteristics. The driver 22 preferably includes a buffer 32 which is provided with the square wave input signal 23, and which provides first control signals to the control electrodes, or terminals, of the of the series connected switches Q1, Q2. The output voltage Vout1 is provided from a node A between the switches Q1, Q2 based on the ON/OFF state of these switches. Thus, the switches Q1, Q2 are controlled via the first control signals to provide the desired first output voltage signal Vout1.

The driver 24 includes a second buffer 34 provided with the input signal 23¹. The second amplifier 34 preferably provides second control signals to control the series connected switches Q3 and Q4. The output voltage Vout2 is provided from a node B positioned between the switches Q3, Q4 and is based on the ON/OFF state of these switches. Thus, the switches Q3, Q4 are controlled via the second control signals to provide the desired second output voltage signal Vout2. Alternatively, the driver 24 may receive the input signal 23, while the driver 22 receives the signal 23¹ or either driver may receive a combination of the signals 23 and 23¹ as an input, if desired.

The driver 24 also preferably includes internal circuitry 34 which may be used to provide additional processing of the second output voltage signal Vout2, if desired. For example, the circuitry 34 may be used to operate feed-back control. As a result, the dv/dt of the voltage provided to the PDP via the external power switch 36 can be controlled by limiting the dv/dt as desired. While the internal circuitry 34 may be used for dv/dt control, the present application is not limited to this embodiment and the internal circuitry 34 may be used to provide any other additional functionality. The output of the internal circuitry 34 thus provides a processed output voltage signal Vout2¹ that is ultimately output from the second driver 24. The internal circuitry 34 may thus be used to ensure the gating characteristics provided by the processed output voltage signal Vout2¹ are different from those provided by the first output voltage signal Vout1.

The driver circuit 20 also preferably includes a selection circuit 38 which is provided with both the first output voltage signal Vout1 from the driver 22 and the processed output voltage signal Vout2¹ from the internal circuitry 34 of the driver 24. The selection circuit 38 is operable to select one of the first output voltage signal Vout1 and the processed output voltage signal Vout2¹ as a gate drive signal to be provided to the gate of the single power switch 36. The gate drive signal controls the ON/OFF state of the switch 36, and thus, the ionizing voltage, or scanning voltage, provided to the PDP.

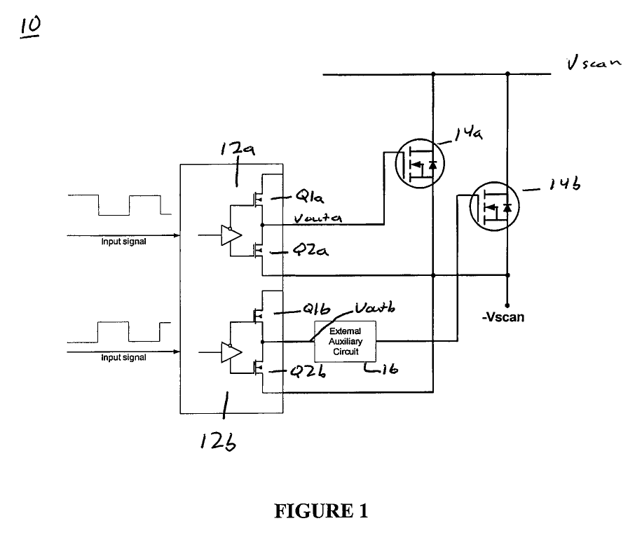

The driver circuit 20 of the present application thus provides multi-function gating with a single external power switch 36. As a result, there is no need to provide an additional external power switch. As illustrated in FIG. 2, in a preferred embodiment, the first and second drivers 22, 24, the internal circuitry 34 and the selection circuit 38 are preferably implemented in a single integrated circuit. Thus, the driver circuit 20 eliminates the external circuit 16 used in the conventional HVIC 10 discussed above with reference to FIG. 1. In addition, both of the drivers 22, 24 preferably share a common ground voltage via a common ground connection. Further, a single gate drive output can be provided for the gate drive signal provided to the switch 36 from the selection circuit 38.

The selection made by the selection circuit 38 is preferably based on at least one of the first and second input signals 23, 23¹. Alternatively, the selection made by the selection circuit 38 may be controlled by any suitable logic unit.

The driver circuit 20 of the present application thus provides multi-function gating using drivers 22, 24 with different gating characteristics while reducing the number of external components necessary. As a result, the driver circuit 20 of the present application reduces the space necessary to implement multi-function gating and also reduces cost since it reduces component count.

Although the present invention has been described in relation to particular embodiments thereof, many other variations and modifications and other uses will become apparent to those skilled in the art. It is preferred, therefore, that the present invention not be limited by the specific disclosure herein.

What is claimed is:

1. A high voltage gate driver circuit comprising:
a first driver operable to provide a first output voltage signal;
a second driver operable to provide a second output voltage signal;
internal circuitry operable to process the second output voltage signal to provide a processed output voltage signal having different characteristics than the first output voltage signal; and
a selection circuit operable to select one of the first output voltage signal and the processed output voltage signal as a gate drive signal.

2. The high voltage gate driver circuit of claim 1, further comprising
an external power switch connected to the selection circuit such that the gate drive signal is provided to the gate of the external power switch to turn the external power switch on and off as desired.

3. The high voltage gate driver circuit of claim 2, wherein the first driver further comprises:
a first driving buffer operable to provide first control signals based on a first input signal;
a first high side switch; and
a first low side switch connected in series with the first high side switch, wherein the first high side switch and the first low side switch are controlled based on the first control signals to provide the first output voltage signal at a first node positioned between the first high side switch and the first low side switch.

4. The high voltage gate driver circuit of claim 3, wherein the second driver further comprises:
a second buffer amplifier operable to provide second control signals based on a second input signal;
a second high side switch; and
a second low side switch connected in series with the second high side switch, wherein the second high side switch and the second low side switch are controlled based on the second control signals to provide the second output voltage signal at a second node positioned between the second high side switch and the second low side switch.

5. The high voltage gate driver circuit of claim 4, wherein the selection circuit selects one of the first output voltage signal and the processed output voltage signal as the gate drive signal based on at least one of the first input signal and the second input signal.

6. The high voltage gate driver circuit of claim 5, wherein the internal circuitry is operable to introduce feed-back control into the second output voltage signal to provide the processed output voltage signal.

7. The high voltage gate driver circuit of claim 6, wherein the selection circuit is operable to select the processed output voltage signal and to provide the processed output voltage signal to the gate of the power switch to control the dv/dt of the driver circuit.

8. The high voltage gate driver circuit of claim 5, wherein the external power switch is turned on and off to control a scanning voltage for a plasma display panel.

9. The high voltage gate driver circuit of claim 8, wherein the first driver, the second driver, the internal circuitry and the selection circuit are implemented in a single integrated circuit.

10. The high voltage gate driver circuit of claim 9, wherein the first driver and the second driver share a common ground connection pin in the single integrated circuit.
